(19) United States
(12) Patent Application Publication
(10) Pub. No.: US 2024/0111930 A1
(43) Pub. Date: Apr. 4, 2024

(54) MODEL PROVIDING ASSISTANCE SYSTEM AND MODEL PROVIDING ASSISTANCE METHOD FOR USING DIGITAL TWIN SIMULATION

(71) Applicant: Hitachi, Ltd., Tokyo (JP)

(72) Inventors: Alexander Adam LAURENCE, Tokyo (JP); Keiro Muro, Tokyo (JP); Daiwa Satoh, Tokyo (JP)

(73) Assignee: Hitachi, Ltd., Tokyo (JP)

(21) Appl. No.: 18/449,031

(22) Filed: Aug. 14, 2023

(30) Foreign Application Priority Data
Sep. 30, 2022 (JP) 2022-158830

(51) Int. Cl. G06F 30/27

(52) U.S. Cl. CPC G06F 30/27

(57) ABSTRACT

A system determines a plurality of model classes of a scenario model based on: different factors with respect to a scenario model for a digital twin simulator, the factors being specified from physical or digital asset; and a result of comparison between a value for the factor and a threshold of each factor. For each of the model classes and for each outcome with respect to the scenario model, the system receives, from a user, an outcome value range that is a range of a value of the each outcome and is a range of a value based on heuristics. The system prepares, for each model class, a scenario model having an outcome value belonging to the outcome value range received for the each model class. The system selects an optimal scenario model from among the scenario models prepared for respective ones of the model classes.

### BACKGROUND OF THE INVENTION

### 1. Field of the Invention

The present invention generally relates to providing a model for using digital twin simulation.

### 2. Description of the Related Art

As a technique related to digital twin simulation, there is a technique disclosed in EP 3916501 A1, for example.

### SUMMARY OF THE INVENTION

As an object in the real world simulated by the digital twin, various objects can be adopted that include a vehicle such as a railway, a device such as an air compressor, or a system including a vehicle or a device (for example, a warehouse or a factory).

A model is used in the digital twin simulation. As the model, it is possible to adopt a machine learning model trained using training data with respect to the real world, for example, using training data whose input data is data collected from one or more sensors and whose output data is data with respect to a state of the real world. Inference is performed using such a machine learning model; specifically, data collected from the real world (for example, one or more sensors) is input, and data representing an estimated state of the real world is output.

However, the data collected from the real world is not necessarily identical or similar to the input data in the training data, and, as a result, the state of the real world estimated by the inference may be significantly different from the actual state of the real world.

As a method to avoid such a problem, a method is considered in which a modeled scenario set is adopted instead of the above-described machine learning model. The “scenario set” is a set of a plurality of scenarios. The “scenario” is an element of the scenario set, and is data including a value that can be included in the input data with respect to each of a plurality of data items. The scenario set can cover many combinations of a plurality of values corresponding to the plurality of data items.

However, this method has a trade-off problem of so-called “curse of dimensionality”. That is, when the number of dimensions (elements) in each scenario is large, a search range of a query for model search is accordingly wide. When the number of dimensions is small, the accuracy of the model (the accuracy of the digital twin simulation) is accordingly low.

A system determines a plurality of model classes that are each a model class of a scenario model, based on: (i) one or more model factors that are one or more different factors with respect to a scenario model for a digital twin simulator, the one or more model factors being specified from physical asset data or digital asset data corresponding the physical asset data; and (ii) a result of comparison, for each model factor of the one or more model factors, between a value with respect to the each model factor and a threshold of the each model factor. For each of the plurality of model classes and for each model outcome of one or more model outcomes that are one or more different outcomes with respect to the scenario model, the system receives, from a user, an outcome value range that is a range of a value of the each model outcome and is a range of a value based on heuristics. The system prepares, for each model class of the plurality of model classes, a scenario model having an outcome value belonging to the outcome value range received for the each model class. The system selects an optimal scenario model from among the scenario models prepared for respective ones of the model classes.

With the present invention, even when a scenario has a large number of dimensions, a high-speed search for an optimal scenario model to be applied to the digital twin simulator is possible.

### BRIEF DESCRIPTION OF THE DRAWINGS

FIG. 1 illustrates a configuration of a whole system including a model providing assistance system according to an embodiment of the present invention;

FIG. 2 illustrates an example of data in each storage area in a storage apparatus;

FIG. 3 illustrates an example of a configuration of data stored in a metadata area and a relationship among the data;

FIG. 4 illustrates an example of a main graphic user interface (GUI);

FIG. 5 illustrates an example of a scenario definition GUI;

FIG. 6 illustrates an example of a heuristics definition GUI;

FIG. 7 illustrates an example of a model selection result GUI;

FIG. 8 illustrates an example of processing performed by an asset modeling unit and a scenario modeling unit;

FIG. 9 illustrates an example of details of Scenario Set generation;

FIG. 10 illustrates an example of details of Scenario Model generation;

FIG. 11 illustrates an example of details of model clustering;

FIG. 12 illustrates an example of processing performed by a caching unit;

FIG. 13 illustrates an example of processing performed by a model selection unit;

FIG. 14 illustrates an example of details of decision tree generation;

FIG. 15 illustrates a first example of the decision tree generation;

FIG. 16 illustrates a second example of the decision tree generation;

FIG. 17 illustrates an example of details of model selection;

FIG. 18 illustrates an example of details of CPU monitoring;

FIG. 19 illustrates an example of details of Asset Health monitoring;

FIG. 20 illustrates an example of details of Data monitoring; and

FIG. 21 illustrates an example of details of query generation.

### DESCRIPTION OF THE PREFERRED EMBODIMENTS

In the following description, an “interface apparatus” may be one or more interface devices. The one or more interface devices may be at least one of the followings.

An input/output (I/O) interface apparatus that is one or more I/O interface devices. The I/O interface device is an interface device for at least one of an I/O device and a remote display computer. The I/O interface device for a display computer may be a communication interface device. The at least one I/O device may be a user interface device, for example, any of the followings: an input device including a keyboard and a pointing device; and an output device including a display device.

A communication interface apparatus that is one or more communication interface devices. The one or more communication interface devices may be one or more communication interface devices of the same type, for example, one or more network interface cards (NIC), or may be two or more communication interface devices of different types, for example, an NIC and a host bus adapter (HBA).

In the following description, a “memory” is one or more memory devices that are an example of one or more storage devices, and may typically be a main storage device. At least one memory device of the memory may be a volatile memory device or a non-volatile memory device.

In addition, in the following description, a “persistent storage apparatus” may be one or more persistent storage devices that are an example of the one or more storage devices. Typically, the persistent storage device may be a non-volatile storage device, for example, an auxiliary storage device, and specifically, may be, for example, a hard disk drive (HDD), a solid state drive (SSD), a non-volatile memory express (NVME) drive, or a storage class memory (SCM).

In addition, in the following description, a “storage apparatus” may be at least the memory of a memory and a persistent storage apparatus.

In the following description, a “processor” may be one or more processor devices. The at least one processor device may typically be a microprocessor device such as a central processing unit (CPU), but may be another type of processor device such as a graphics processing unit (GPU). The at least one processor device may have a single core or multi cores. The at least one processor device may be a processor core. The at least one processor device may be a processor device in a broad sense such as a circuit that is an aggregate of gate arrays in a hardware description language, performs a part or all of processing, and is, for example, a field-programmable gate array (FPGA), a complex programmable logic device (CPLD), or an application specific integrated circuit (ASIC).

In addition, in the following description, functions such as a checker and a database management system (DBMS) may be described, and the functions may be implemented by one or more computer programs being executed by a processor, may be implemented by one or more hardware circuits (for example, FPGA or ASIC), or may be implemented by a combination thereof. In a case where a function is implemented by a program being executed by a processor, prescribed processing is appropriately performed using a storage apparatus and/or an interface apparatus, and the function may therefore be construed as at least a part of the processor. Processing described with a function as the subject of the processing may be construed as processing performed by a processor or a device including the processor. The program may be installed from a program source. The program source may be, for example, a program distribution computer or a computer-readable storage medium (for example, a non-transitory storage medium). The description of each function is an example, and a plurality of functions may be integrated into one function, or one function may be divided into a plurality of functions.

In addition, in the following description, in a case where the same kind of elements are described without being distinguished from each other, a common sign among reference signs may be used, and in a case where the same kind of elements are distinguished from each other, reference signs may be used.

Hereinafter, a model providing assistance system according to an embodiment of the present invention will be described with reference to the drawings. The model is a model used for digital twin simulation. In the following description, terms are as follows.

A “real world” is the world simulated by a digital twin, in other words, the world to be reproduced by a digital twin.

A “physical asset” is a physical object (for example, a train, a robot, an air compressor, a car, or the like) in the real world. There are one or more physical assets in the real world, but in a case where there is one physical asset in the real world, the physical asset and the real world may be synonymous. In the following embodiments, for ease of description, the physical asset and the real world are synonymous.

A “virtual world” is a world provided by a digital twin and is a simulation of a real world.

A “digital asset” may be referred to as a virtual asset, and is a digital copy of the physical asset. The digital asset may be an object modeled based on data collected with respect to the real world (for example, data from a sensor).

A “Feature” means a feature as a data item (for example, a variable item). A data item value (for example, a variable value) can be expressed as a “feature” (Feature Value).

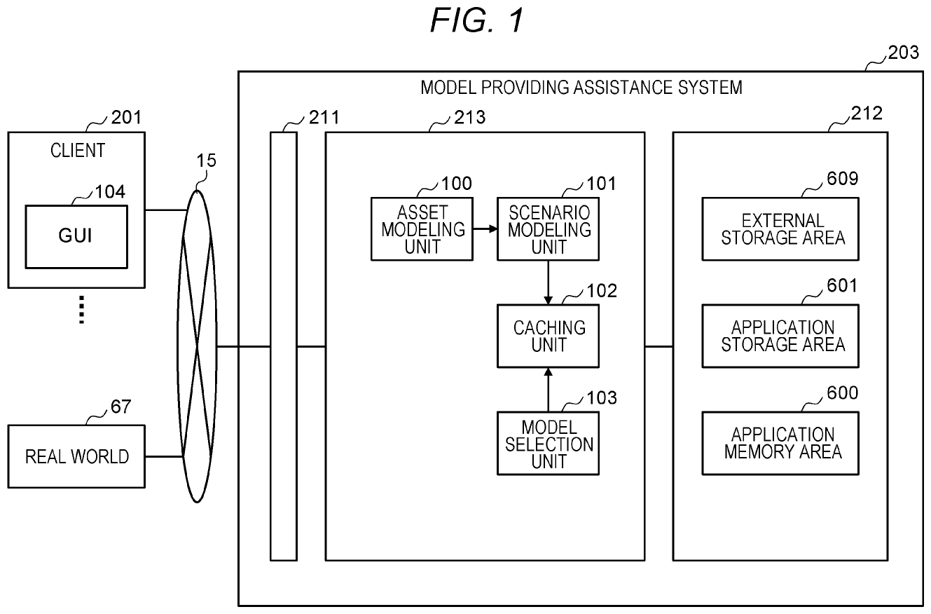

FIG. 1 illustrates a configuration of a whole system including the model providing assistance system according to the embodiment of the present invention.

A client terminal 201 and a model providing assistance system 203 are connected to a communication network 15, for example, the Internet or a wide area network (WAN). In addition, communication devices (for example, a sensor and a gateway) in a real world 67 are also connected to the communication network 15.

The client terminal 201 is an information processing terminal such as a personal computer or a smartphone, but may be a virtual information processing terminal (for example, a virtual machine or a virtual desktop). The client terminal 201 executes a computer program such as a web browser. As a result, a user interface (UI) such as a graphical user interface (GUI) 104 is displayed. The client terminal 201 transmits a request to the model providing assistance system 203 and receives a response from the model providing assistance system 203. Hereinafter, an operator of the client terminal 201 is referred to as the “user”.

The model providing assistance system 203 is a physical computer system, but may be a logical computer system based on a physical computer system (for example, a cloud service system based on a cloud infrastructure). The model providing assistance system 203 receives data (for example, data measured by a sensor) from the real world 67. In addition, the model providing assistance system 203 receives data that is input via the GUI 104. The model providing assistance system 203 includes an interface apparatus 211, a storage apparatus 212, and a processor 213 connected to the interface apparatus 211 and the storage apparatus 212.

The interface apparatus 211 communicates with the client terminal 201 (and a communication device in the real world 67.) via the communication network 15.

The storage apparatus 212 includes storage areas including an external storage area 609, an application storage area 601, and an application memory area 600. In addition, the storage apparatus 212 stores a computer program to be executed by the processor 213.

The processor 213 executing a computer program implements functions such as an asset modeling unit 100, a scenario modeling unit 101, a caching unit 102, and a model selection unit 103.

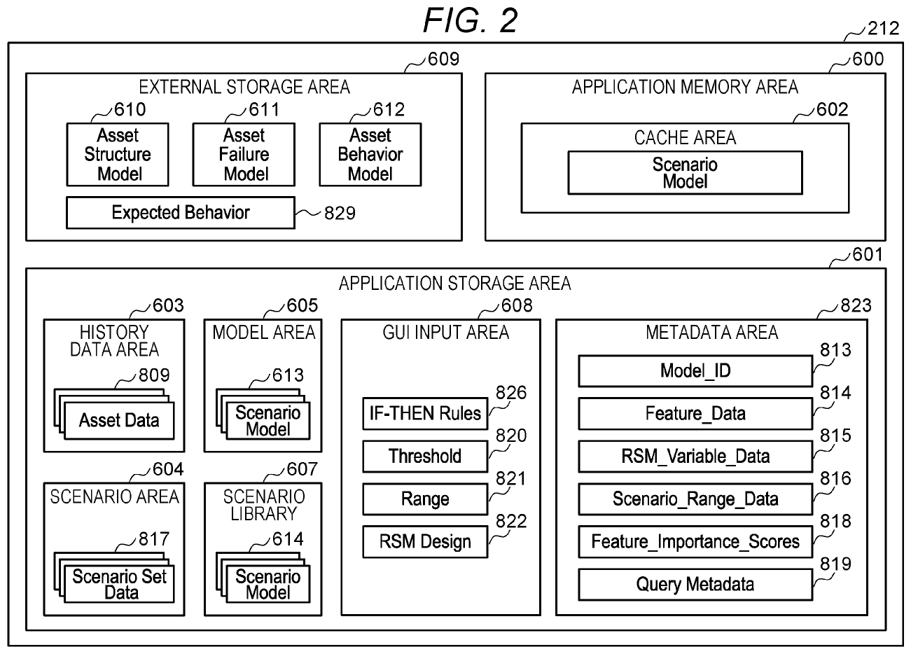

FIG. 2 illustrates an example of data in each storage area in the storage apparatus 212.

The external storage area 609 stores an Asset Structure Model 610, an Asset Failure Model 611, an Asset Behavior Model 612, and an Expected Behavior 829. The application memory area 600 includes a cache area 602, and the cache area 602 stores a Scenario Model.

The application storage area 601 includes a history data area 603, a scenario area 604, a model area 605, a scenario library 607, a GUI input area 608, and a metadata area 823.

The history data area 603 stores Asset Data 809 of the physical asset. The Asset Data 809 may exist every predetermined period (for example, daily, monthly). That is, a history of the Asset Data 809 may be stored. The Asset Data 809 represents a feature (for example, a value measured by a sensor) and acquisition date and time of the feature for each of one or more Features with respect to the physical asset. The Asset Data 809 may be time-series data of a feature for each of one or more Features with respect to the physical asset. The Asset Data 809 may be input from the GUI 104 or may be input from the real world 67.

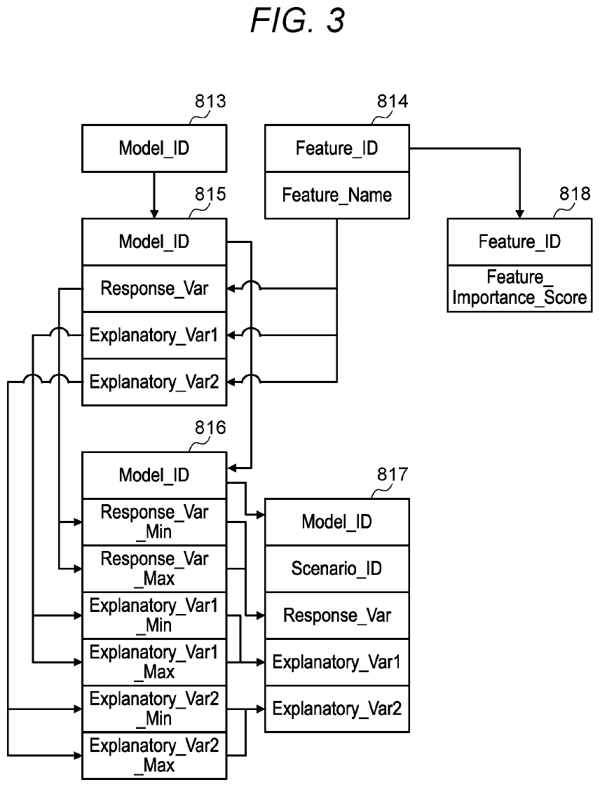

The scenario area 604 stores Scenario Set Data 817. The Scenario Set Data 817 exists for each scenario set. Details of the Scenario Set Data 817 will be described later with reference to FIG. 3.

The model area 605 stores Scenario Models 613. The scenario library 607 is a library of Scenario Models, and specifically stores, for example, clustered Scenario Models 614, among the Scenario Models 613 stored in the model area 605.

The GUI input area 608 stores metadata related to GUI input, specifically, data such as IF-THEN Rules 826, Threshold 820, Range 821, and RSM Design 822.

The IF-THEN Rules 826 are data referred to in processing by the model selection unit 103 and represents one or more if-then rules.

The Threshold 820 is data referred to in processing by the model selection unit 103, and represents a threshold for each of a plurality of data items (for example, a failure rate and a CPU usage rate).

The Range 821 is data representing a value range (for example, a combination of a minimum value and a maximum value of a feature) for each Feature.

The RSM Design 822 is data related to a specification or design of a response surface methodology (RSM) model, and represents, for each of one or more types of RSM models, a type of the RSM model and a parameter that can be used for the RSM model, for example.

The metadata area 823 stores metadata related to model providing assistance, specifically, Model_ID 813, Feature_Data 814, RSM_Variable_Data 815, Scenario_Range_Data 816, Feature_Importance_Scores 818, and Query Metadata 819. Details of the data 813 to 816 and 817 will be described later with reference to FIG. 3.

The Query Metadata 819 is metadata of a query received from the client terminal 201. The Query Metadata 819 has an entry for each query. The entry indicates a Query_Key (an ID or a name of Feature as a Key specified by a query), a Query_Value (a value as a Value corresponding to the Key specified by a query [the value is the ID of the Feature of each of a first and second explanatory variables]), and a Count (the number of times of the query).

FIG. 3 illustrates an example of a configuration and a relationship of and between the Scenario Set Data 817 and data in the metadata area 823.

The Model_ID 813 has data representing an ID for each Scenario Model.

The Feature_Data 814 is data representing a Feature_ID (ID of Feature) and a Feature_Name (name of Feature) for each Feature.

The RSM_Variable_Data 815 is data representing a set of an objective variable and an explanatory variable group for each Scenario Model. The RSM_Variable_Data 815 has an entry for each Scenario Model. The entry has data such as a Model_ID, a Response_Var, an Explanatory_Var1, and an Explanatory_Var2. The Model_ID represents an ID of the Scenario Model. The Response_Var means an objective variable, and the value of the Response_Var may be the ID of the Feature. The Explanatory_Var1 and the Explanatory_Var2 mean a first explanatory variable and a second explanatory variable, and each value may be an ID of the corresponding Feature. Specifically, the name of the Feature can be specified from the Feature_Data 814 by using the ID of the Feature of Response_Var, the Explanatory_Var1, or the Explanatory_Var2.

Note that the “explanatory variable group” means one or more explanatory variables, and in the illustrated example, the number of explanatory variables is two. This is because an example of the Scenario Model is a 3D Reynolds stress model (RSM). The Explanatory_Var is provided for each explanatory variable. For example, when the Feature as the objective variable is “temperature”, the Feature as the first explanatory variable may be “Illumination Outcome”, and the Feature as the second explanatory variable may be “rotation speed”.

When a model other than the 3D RSM is adopted as the Scenario Model, the number of variables may be more than or less than three. The number of variables may be designated from the GUI 104, but, in the present embodiment, the number of variables may be determined by a heuristic logic function (for example, Heuristics execution 109, see FIG. 13) implemented by the processor 213.

Scenario_Range_Data 816 is data representing, for each Scenario Model, the value range of the objective variable (the range of the feature) and the value range of each explanatory variable. The data representing the value range of the objective variable is configured with a Response_Var_Min (data representing the minimum value of the objective variable) and a Response_Var_Max (data representing the maximum value of the objective variable). The data representing the value range of the first explanatory variable is configured with an Explanatory_Var1_Min (data representing the minimum value of the value of the first explanatory variable) and an Explanatory_Var1_Max (data representing the maximum value of the value of the first explanatory variable). The data representing the value range of the second explanatory variable is configured an Explanatory_Var2_Min (data representing the minimum value of the value of the second explanatory variable) and an Explanatory_Var2_Max (data representing the maximum value of the value of the second explanatory variable). The expression of the value range does not need to be a combination of the minimum value and the maximum value.

The Scenario Set Data 817 has an entry for each scenario. The entry is data representing the scenario, and specifically has data such as the Model_ID, a Scenario_ID, the Response_Var, the Explanatory_Var1, and the Explanatory_Var2. The Model_ID represents the ID of the Scenario Model corresponding to the scenario. The Scenario_ID represents an ID of the scenario. The Response_Var represents one of values that can be taken as the objective variable. The Explanatory_Var1 represents one of values that can be taken as the first explanatory variable. The Explanatory_Var2 represents one of values that can be taken as the second explanatory variable.

One Scenario Model is based on a scenario set, and the scenario set is configured with a plurality of scenarios. A scenario set configured with a plurality of scenarios are based on a plurality of combinations of values of the objective variables, the first explanatory variables, and the second explanatory variables. Specifically, the value represented by each and every Explanatory_Var1 corresponding to one scenario set is the same value as any of the value represented by the Explanatory_Var1_Min and the value represented by the Explanatory_Var1_Max or is a value between the two values.

The Feature_Importance_Scores 818 is data representing, for each Feature, the ID of the Feature (Feature_ID) and a degree of importance of the Feature (Feature_Importance_Score).

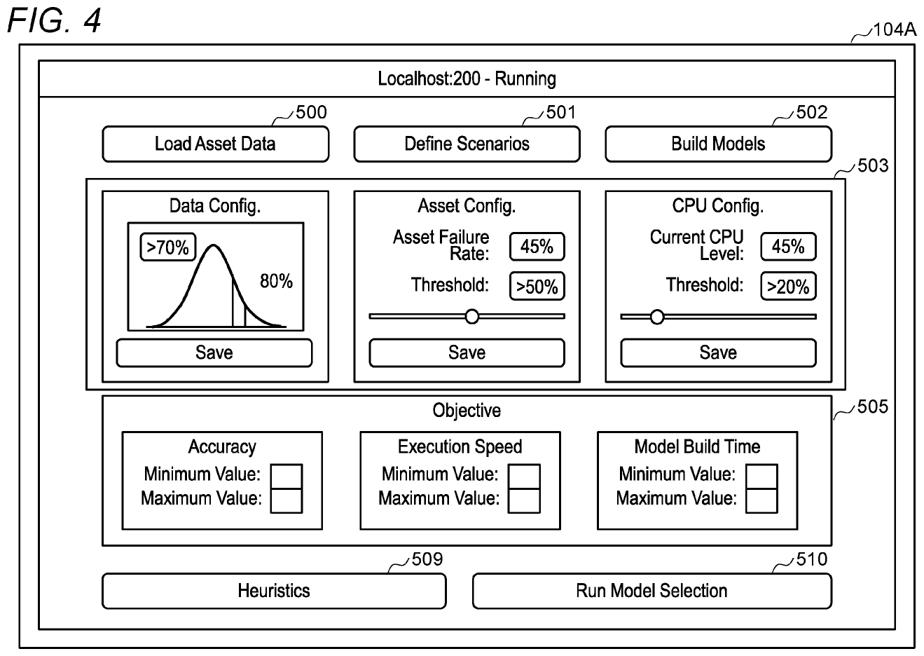

Hereinafter, an example of the GUI 104 will be described with reference to FIGS. 4 to 7. Note that, in the following description, any component such as a check box, a text box, or a button may be adopted as an example of the GUI component.

FIG. 4 illustrates an example of the main GUI 104A.

The main GUI 104A is a top GUI provided (displayed) to the client terminal 201. The main GUI 104A includes, for example: a button 500 to receive a request for loading the Asset Data 809; a button 501 to receive a request for scenario definition; a button 502 to receive a request for model building; a button 509 to receive a request for an input of Heuristics; and a button 510 to receive a request for execution of model selection.

The main GUI 104A includes a GUI component group 503 that receives inputs of various thresholds. Examples of the threshold include a threshold related to statistics (for example, distribution) specified from the Asset Data 809, a threshold of a failure rate specified from the Asset Data 809, and a threshold of a CPU usage rate specified from the Asset Data 809. The threshold that is input via the GUI component group 503 is included in the Threshold 820.

The main GUI 104A further includes: a GUI component group 505 (for example, a text box group) that receives an input of a requirement (a range of an Outcome value) for each of a plurality of Outcomes (for example, accuracy, an execution speed; and a building requirement time) of a Scenario Model. When a requirement for each Outcome is input to the GUI component group 505 and the button 502 or the button 510 is then pressed, the model providing assistance system 203 builds or selects the Scenario Model that satisfies the requirement. Alternatively or in addition, an Outcome value range associated with each model class to be described later may be an input to the GUI component group 505.

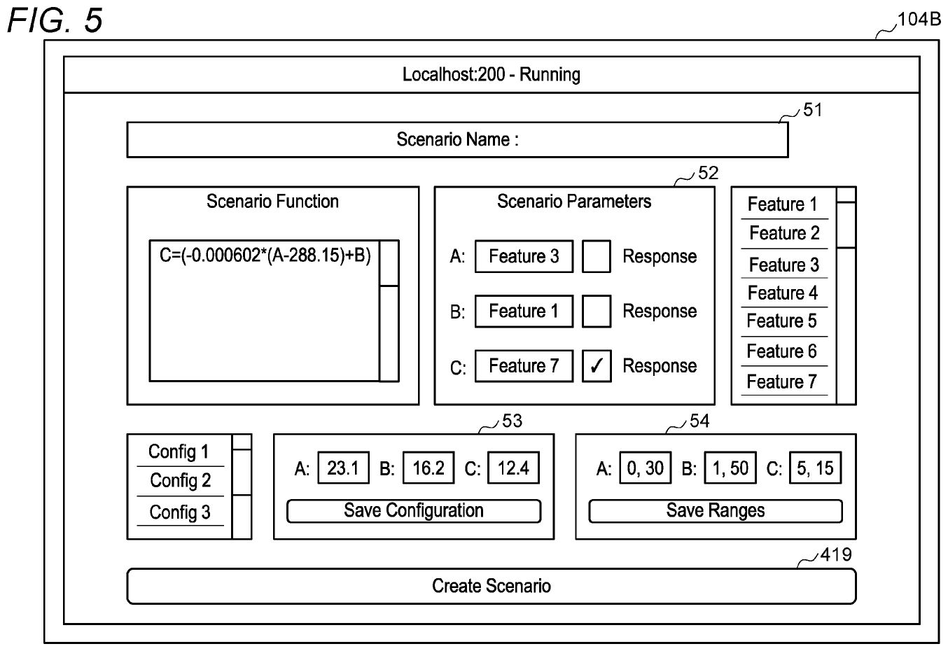

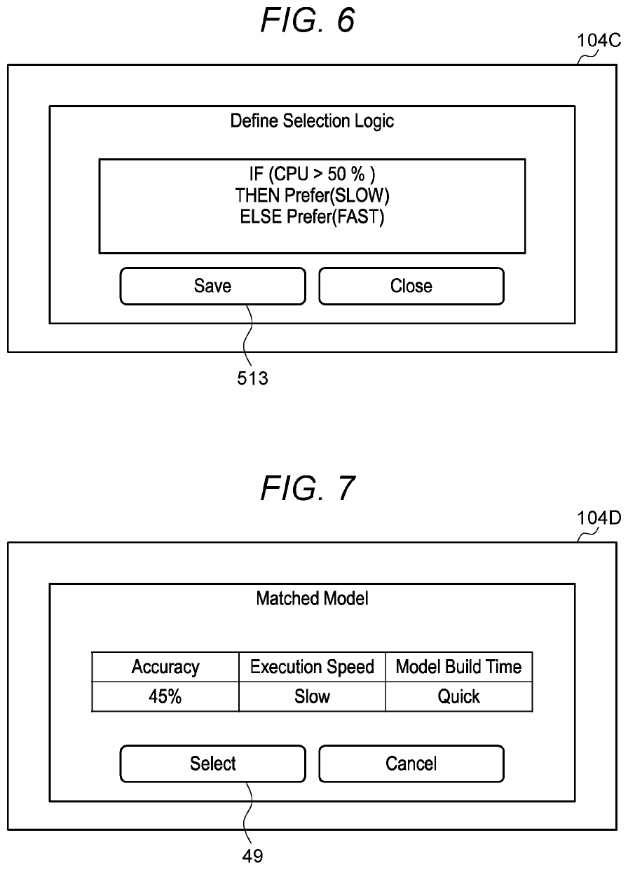

For example, in a case where the button 501 is pressed by the user, a scenario definition GUI 104B (see FIG. 5) is provided to the client terminal 201. Furthermore, for example, in a case where the button 509 is pressed by the user, a Heuristics definition GUI 104C (see FIG. 6) is provided to the client terminal 201. Furthermore, for example, in a case where the button 510 is pressed by the user, model selection processing is executed, and a model selection result GUI 104D (see FIG. 7) is provided to the client terminal 201.

FIG. 5 illustrates an example of the scenario definition GUI 104B.

The scenario definition GUI 104B is a GUI that receives an input of a definition related to a scenario. The scenario definition GUI 104B includes, for example: a GUI component 51 (for example, a text box) that receives an input of a scenario name; a GUI component group 52 that receives an input of a variable set as a scenario (for example, the GUI component group 52 receives, for each variable as a scenario, inputs of the ID of a Feature and of whether the variable is an objective variable or an explanatory variable); a GUI component group 53 that receives an input of a variable value (feature) for each variable (Feature); a GUI component group 54 that receives an input of a value range (for example, a combination of a minimum value and a maximum value) for each variable; and a button 49 that receives a request for scenario creation. When the button 49 is pressed by the user, the Scenario Set Data 817 (alternatively, the Scenario Data that is an element of the Scenario Set Data 817 and is data representing a scenario) is generated in accordance with the data that is input to the scenario definition GUI 104B.

FIG. 6 illustrates an example of the Heuristics definition GUI 104C.

The Heuristics definition GUI 104C is a GUI that receives an input of Heuristics definition data such as an if-then rule. For example, in the case where the rule having been input is data of the if-then rule having been input, the data is stored as some of or all of the IF-THEN Rules 826 when a button 513 in the GUI 104C is pressed.

FIG. 7 illustrates an example of the model selection result GUI 104D.

The model selection result GUI 104D is a GUI that displays the result of model selection processing. As a result, for example, performance information of the Scenario Model found as a selection candidate is shown (for example, the performance information is specific values of respective ones of accuracy, execution speed, and model building time or the Outcomes to which the values belong). From the displayed performance information, the user determines whether or not to select (approve) the Scenario Model that is selected as the selection candidate, and when selecting the Scenario Model, the user presses the button 49 for notifying the system 203 of the intention to select. When the button 49 is pressed, the Scenario Model is recognized as a Scenario Model for using digital twin simulation (for example, it is deployed in a simulator that performs digital twin simulation).

Hereinafter, an example of processing that is performed in the present embodiment will be described.

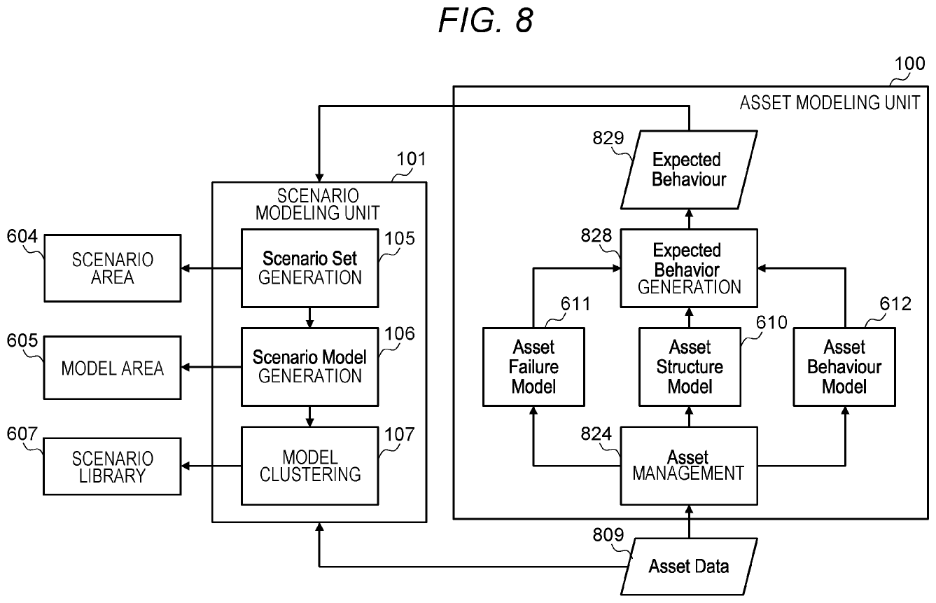

FIG. 8 illustrates an example of the processing that is performed by the asset modeling unit 100 and the scenario modeling unit 101.

The asset modeling unit 100 performs Asset management 824 and Expected Behavior generation 828.

In the Asset management 824, the asset modeling unit 100 reads out the Asset Data 809 of the physical asset, specifies data for each of the models 610 to 612 from the Asset Data 809, and inputs the specified data to the model. Each of the models 610 to 612 outputs data obtained based on the input data. Data including the data having been output from each of the models 610 to 612 (for example, data including a time series of predicted sensor data [sensor measurement value]) is the Expected Behavior 829.

Each of the models 610 to 612 may be a model built by the asset modeling unit 100 using the past Asset Data 809 as at least a part of the training data. Each of the models 610 to 612 corresponds to some of the models of the digital asset corresponding to the physical asset. The model of the digital asset may be configured as one model, but in the present embodiment, a set of models (for example, machine learning models) each prepared for one of viewpoints may be used. The viewpoints include, in the present embodiment, “configuration”, “failure”, and “normal operation”.

A model corresponding to the “configuration” is the Asset Structure Model 610. The Asset Structure Model 610 is a model whose input is telemetry data (for example, time-series data of performance) specified from the Asset Data 809 and whose output is data related to an operation of the physical asset. The telemetry data may include time series of features with respect to all or some of explanatory variables.

A model corresponding to “failure” is the Asset Failure Model 611. The Asset Failure Model 611 is a model whose input is failure data specified from the Asset Data 809 (for example, data representing a failure rate, and data that represents a feature meaning failure and represents a date and time of occurrence of the failure) and whose output is data related to the operation of the physical asset. The failure data may include at least either time series of features with respect to all or some of the explanatory variables (for example, explanatory variables other than the explanatory variables included in the telemetry data) or a time series of the feature with respect to the objective variable.

A model corresponding to the “normal operation” is the Asset Behavior Model 612. The Asset Behavior Model 612 is a model whose input is normal operation data (for example, time-series data of features representing a normal operation) specified from the Asset Data 809 and whose output is data related to an operation of the physical asset. The normal operation data may include at least either time series of features with respect to all or some of the explanatory variables (for example, explanatory variables other than the explanatory variables included in the telemetry data, or the same explanatory variable as the explanatory variable included in the failure data) or a time series of the feature with respect to the objective variable.

In the Expected Behavior generation 828, the asset modeling unit 100 generates the Expected Behavior 829 including the data that is output from the models 610 to 612. The asset modeling unit 100 outputs the Expected Behavior 829 to the scenario modeling unit 101. The Expected Behavior 829 is data (for example, data including a time series of an expected feature for each Feature) related to the operation of the digital asset corresponding to the physical asset.

The Expected Behavior 829 is input to the scenario modeling unit 101. The scenario modeling unit 101 performs Scenario Set generation 105, Scenario Model generation 106, and model clustering 107.

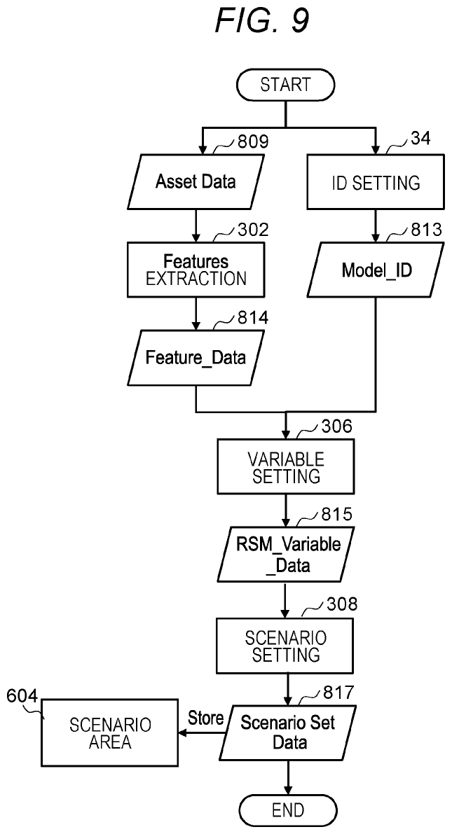

FIG. 9 illustrates an example of details of the Scenario Set generation 105.

The scenario modeling unit 101 performs Features extraction 302. In the Features extraction 302, the scenario modeling unit 101 specifies the Feature from the Asset Data 809 (for example, a time-series CSV file), generates the Feature_Data 814 (for example, upon user's designation of an ID and a name of each Feature), and stores the Feature_Data 814 in the metadata area 823.

The scenario modeling unit 101 performs ID setting 34. In the ID setting 34, the scenario modeling unit 101 generates the Model_ID 813 as a list of IDs assigned to the Scenario Model (for example, generating a list of IDs automatically or manually input), and stores the Model_ID 813 in the metadata area 823.

The scenario modeling unit 101 performs variable setting 306. In the variable setting 306, the scenario modeling unit 101 defines the objective variable and the first and second explanatory variables, generates the RSM_Variable_Data 815 including the defined variables (and the model ID), and stores the RSM_Variable_Data 815 in the metadata area 823. This definition may be made based on a user's input.

The scenario modeling unit 101 performs scenario setting 308. In the scenario setting 308, the scenario modeling unit 101 generates Scenario Set Data 817 on the basis of the RSM_Variable_Data 815, and stores the Scenario Set Data 817 in the scenario area 604. Specifically, for example, the scenario modeling unit 101 refers to the Range 821, specifies a value range for each of the objective variable and the first and second explanatory variables, generates the N number of possible combinations of the value of the objective variable, the value of the first explanatory variable, and the value of the second explanatory variable (where N is an integer of 2 or more), and generates the Scenario Set Data 817 having an entry including each combination as the Scenario Data.

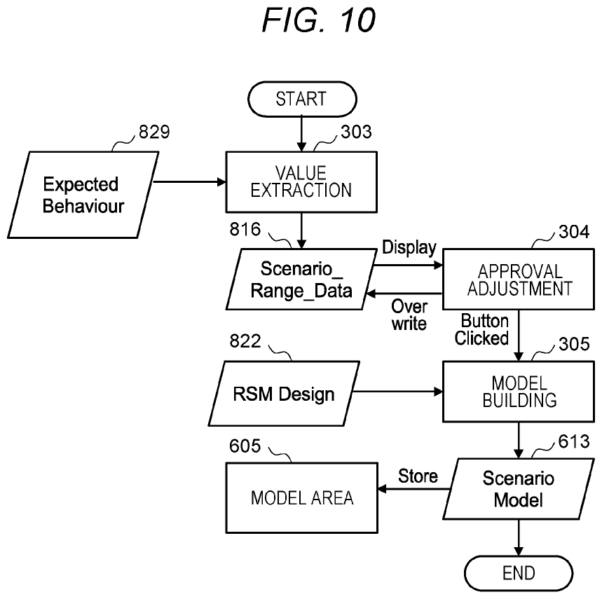

FIG. 10 illustrates an example of details of the Scenario Model generation 106.

The scenario modeling unit 101 performs value extraction 303. In the value extraction 303, the scenario modeling unit 101 specifies a value range for each of the objective variable and the first and second explanatory variables from the Expected Behavior 829 (for example, the maximum value and the minimum value of the feature are specified.). The scenario modeling unit 101 generates the Scenario_Range_Data 816 representing the specified value range for each of the objective variable and the first and second explanatory variables, and stores the Scenario_Range_Data 816 in the metadata area 823.

The scenario modeling unit 101 performs approval adjustment 304. In the approval adjustment 304, the scenario modeling unit 101 displays each value range represented by the Scenario_Range_Data 816, and receives approval or adjustment from the user. When adjustment is received, the value range is updated according to the user's input.

In a case where approval is obtained in the approval adjustment 304, the scenario modeling unit 101 performs model building 305. In the model building 305, the scenario modeling unit 101 builds the Scenario Models 613 as an RSM model on the basis of the RSM Design 822 (one or more parameters of the RSM model), and stores the Scenario Models 613 in the model area 605. The Scenario Model 613 is a model that predicts a value of the objective variable.

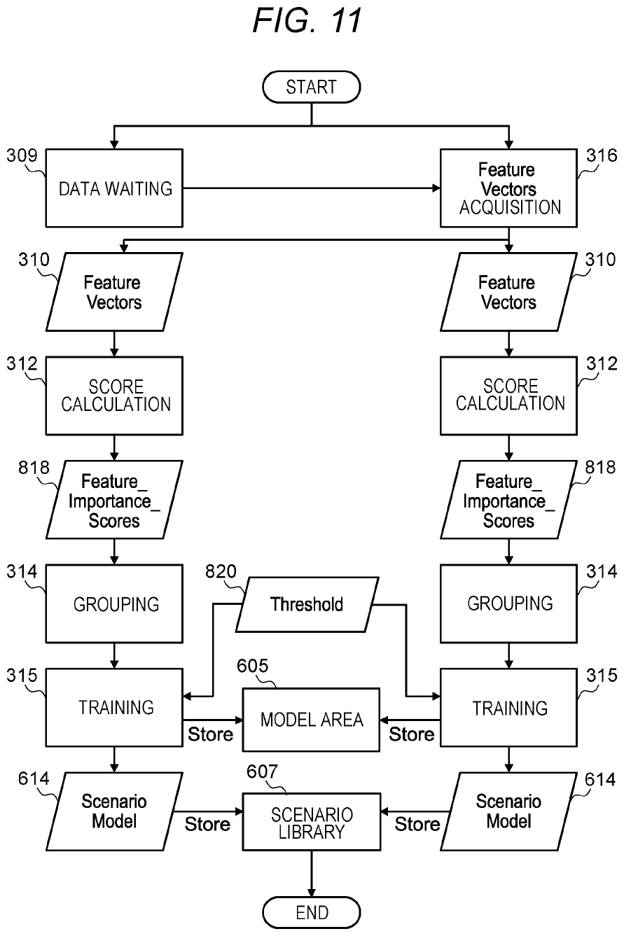

FIG. 11 illustrates an example of details of the model clustering 107.

The scenario modeling unit 101 performs Feature Vectors acquisition 316 by performing the data waiting 309 (waiting for a sufficient amount of Scenario Set Data 817 to perform the model clustering 107) or without performing the data waiting 309. In the Feature Vectors acquisition 316, the scenario modeling unit 101 generates Feature Vectors 310 from the Scenario Set Data 817. Feature Vectors 316 are vector data of features included in the Scenario Set Data 817.

The scenario modeling unit 101 performs score calculation 312. In the score calculation 312, the scenario modeling unit 101 generates Feature_Importance_Scores 818 representing respective ones of the features, and stores the Feature_Importance_Scores 818 in the metadata area 823. The score of each feature (for example, the weight of the variable) may be determined by any of the following methods.

For each feature, the score is input from the user via the GUI 104.

The scenario modeling unit 101 automatically determines the score of each feature (for example, the objective variable and the first and second explanatory variables). For example, the scenario modeling unit 101 divides the feature into k number of groups (for example, k=3) for each feature on the basis of the Feature Vectors 316, and generates an RSM model for each group. The value of k may be a value input via the Heuristics definition GUI 104C (see FIG. 6). The scenario modeling unit 101 calculates the accuracy of the RSM model for each group, and determines a score of feature on the basis of a level of the accuracy.

The scenario modeling unit 101 performs grouping 314. In the grouping 314, the scenario modeling unit 101 divides a plurality of features of a plurality of features (for example, the objective variable and the first and second explanatory variables) into k number of groups (for example, k=3) on the basis of, for example, the Feature Vectors 316.

The scenario modeling unit 101 performs training 315. In the training 315, for each group, the scenario modeling unit 101 prepares the Scenario Model (RSM model) on the basis of the Scenario Model generated in FIG. 10, and performs training (learning) of the Scenario Model. The training (learning) of the Scenario Model may be training according to a regression method, and the training data may be a feature set belonging to the group. The scenario modeling unit 101 specifies accuracy thresholds (for example, a minimum value and a maximum value) from the Threshold 820, and stores the Scenario Model in the model area 605 when the accuracy of the Scenario Model satisfies a condition based on the accuracy thresholds (for example, when the accuracy is more than or equal to the minimum value and less than or equal to the maximum value). A low-accuracy Scenario Models and a high-accuracy Scenario Model is generated in the training on the basis of the score of feature (Importance Score).

In the training 315, the scenario modeling unit 101 clusters the Scenario Models on the basis of accuracy. For example, when k=3 (k is the number of clusters), a cluster of high-accuracy Scenario Models, a cluster of medium-accuracy Scenario Models, and a cluster of low-accuracy Scenario Models may be generated. An intermediate value of accuracy may be generated on the basis of the maximum value and the minimum value of the accuracy threshold, and the clustering may be performed on the basis of the minimum value, the intermediate value, and the maximum value.

Furthermore, in the grouping 314 and the training 315, the scenario modeling unit 101 may apply an arbitrary clustering algorithm (for example, may apply the clustering algorithm from the GUI), and may separate (cluster) the models on the basis of one or more criteria among one or a plurality of criteria such as accuracy, speed, S/N ratio, and query hit rate.

In addition, clustering is useful for generating a plurality of models on the basis of different user requirements. For example, the user who does not care about accuracy (for example, up to a limit of 70%) but wants a quick result can select a low accuracy and high-speed model.

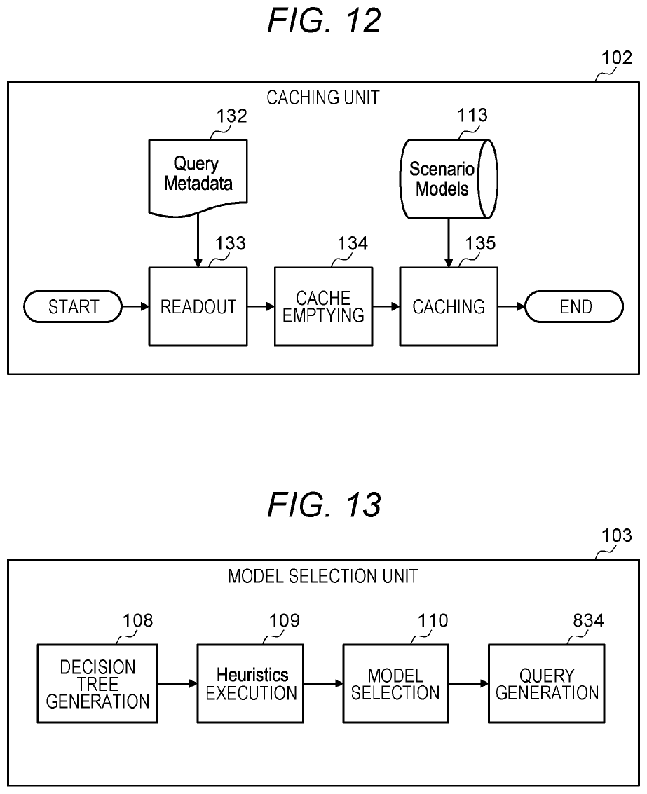

FIG. 12 illustrates an example of processing performed by the caching unit 102.

The caching unit 102 performs readout 133. In the readout 133, the caching unit 102 reads out the Query Metadata 819.

The caching unit 102 performs cache emptying 134. In the cache emptying 134, the caching unit 102 empties one or more cache blocks in the cache area 602.

The caching unit 102 performs caching 135. In the caching 135, the caching unit 102 selects, from Scenario Models 113, the Scenario Model corresponding to the query having the largest Count (number of times of query), on the basis of the Query Metadata 819 (where, from the selected Scenario Model, a value for a key corresponding to a value in the query having the largest Count is obtained), and stores the selected Scenario Model in an empty cache block. The Scenario Models 113 may include the Scenario Models generated by the scenario modeling unit 101 and/or the model selection unit 103 (in other words, the Scenario Models in the model area 605 and/or the scenario library 607).

FIG. 13 illustrates an example of processing performed by the model selection unit 103.

The model selection unit 103 performs decision tree generation 108 including readout of the Threshold 820. As a result, a plurality of model classes, which are a plurality of classes with respect to the Scenario Model, are obtained on the basis of various thresholds.

The model selection unit 103 performs Heuristics execution 109. In the Heuristics execution 109, the model selection unit 103 executes an action according to Heuristics (user definition) such as IF-THEN Rules 826.

The model selection unit 103 performs model selection 110. In the model selection 110, the model selection unit 103 selects a Scenario Model.

The model selection unit 103 performs query generation 834. The model selection unit 103 can automatically generate a query and request a value from the Scenario Models (for example, the scenario library 607).

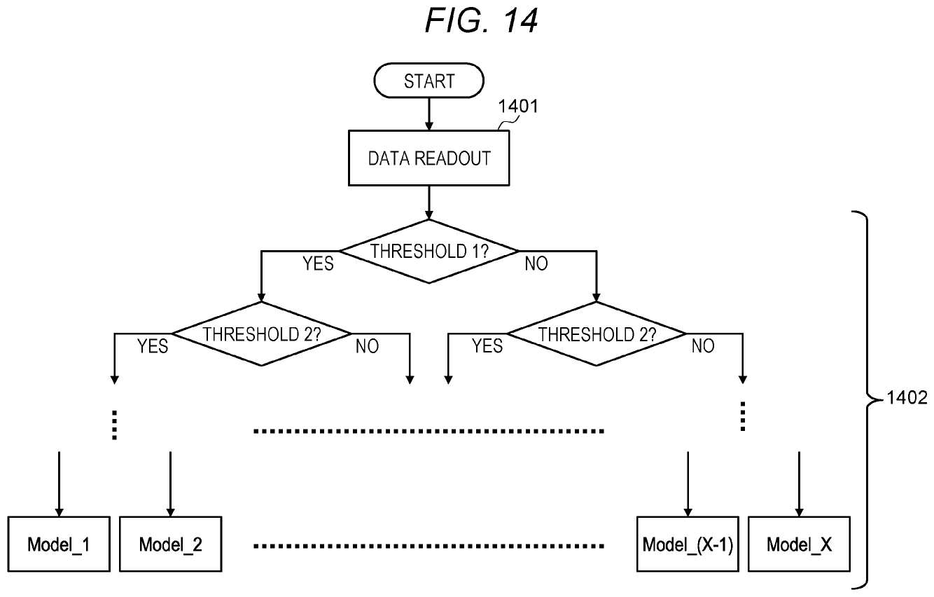

FIG. 14 illustrates an example of details of the decision tree generation 108.

The model selection unit 103 performs data readout 1401. In the data readout 1401, the model selection unit 103 reads out the Asset Data 809 and the Threshold 820.

The Asset Data 809 may include a value with respect to each of a plurality of Factors, for example, a value related to a condition of a physical asset, a value of a CPU load (for example, a CPU usage rate or the number of PCB slots), a value as a sensor measurement value, and a Factor value representing an input type (for example, whether input data is Calculated Data or Modelled Data). Hereinafter, as for each Factor, the Factor may be an item, and a Factor value may be a value about the Factor. For example, when a Factor is the CPU load, the Factor value may be an obtained numerical value.

The Threshold 820 may include a threshold for each Factor such as a threshold of a Factor value related to a condition, a threshold of a CPU usage rate, a threshold of a sensor measurement value, a threshold of a Factor value representing the input type, or the like. There are m number of Outcomes under n number of Factors, where n and m are each an integer greater than or equal to 1 (typically an integer greater than or equal to 2). Equation m=n−1 may be satisfied. The relationship between m and n is not limited to this example. The Outcome may be an outcome as an attribute of the Scenario Model (an outcome of accuracy [model accuracy], execution speed, or building requirement time). As for each Outcome, the Outcome may be an item, and the Outcome value may be a value about the Outcome. For example, when the Outcome is accuracy, the Outcome value may be a numerical value.

The model selection unit 103 performs determination 1402. In the determination 1402, for each Factor value read out in the data readout 1401, the model selection unit 103 compares the Factor value with the threshold of the Factor value. In the present embodiment, for each Factor value, the comparison between the Factor value and the threshold results in two cases: where the Factor value satisfies a condition based on the threshold; and where the Factor does not satisfy, and the number of types of the Factor values is n (that is, the number of thresholds is n). Therefore, a model class number X is 2n (n power of 2). As described above, the number of model classes is based on the number of possible comparison results between the Factor value and the thresholds and on the number of the Factors. The number of possible comparison results may be different depending on the Factor (depending on thresholds).

For each of the m number of Outcomes, the Outcome value of the Outcome is provided for each model class. That is, for each of the Outcomes, the model selection unit 103 determines the range of the Outcome value for each model class on the basis of the comparison result (the comparison result between the Factor value and the threshold) corresponding to the model class. Therefore, there are combinations of outcome value ranges (combinations of Outcome value ranges of m number of Outcomes) for each model class. For each of the m number of Outcomes, the Outcome value range may be set by the user via the GUI 104 on the basis of Heuristics.

The model selection unit 103 generates or selects one Scenario Model for each model class. That is, X number of Scenario Models are generated or selected (one of these Scenario Models is cached by the caching unit 102). As for the generated or selected Scenario Models, each model class of the Scenario Models belongs to an Outcome value range belonging to the model class. For at least one Outcome, the Outcome value range may be configured with one Outcome value.

In the determination 1402, for respective ones of the plurality of Factors, the comparison between the Factor values and the thresholds may be parallelly performed, or may be serially performed as illustrated in FIG. 14. For example, the Factor has a priority, and the Factor value and the threshold may be compared in a descending order of the priority.

A first example and a second example of the decision tree generation 108 will be described.

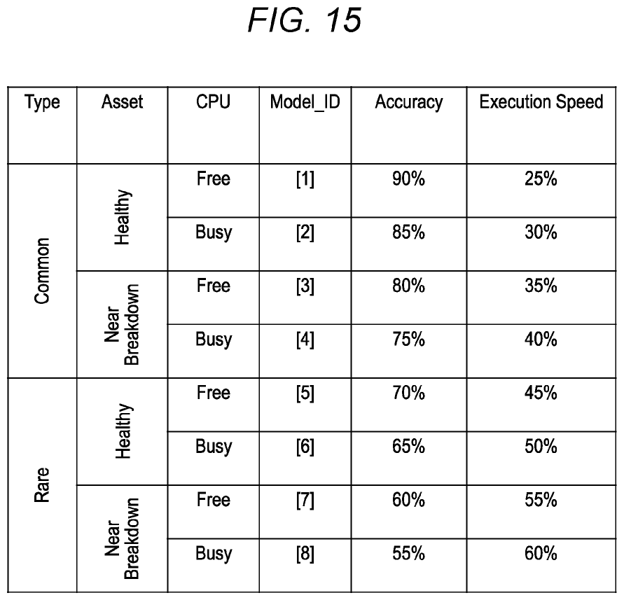

FIG. 15 illustrates the first example of the decision tree generation 108.

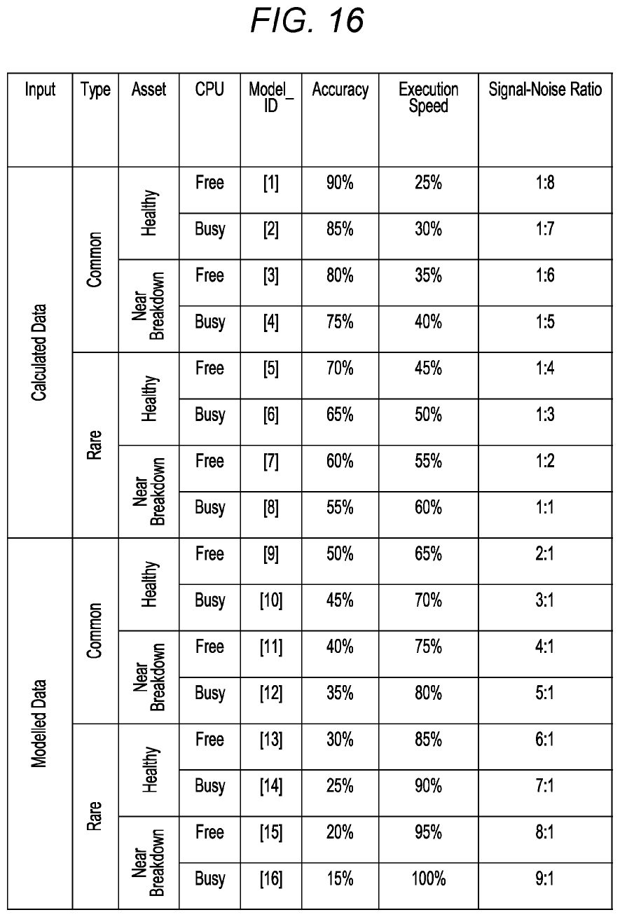

There are three Factors (Data type, Asset Status, and CPU Status), and there are two Outcomes (Accuracy, Execution Speed) under the three Factor. Since n=3, eight model classes are generated (8=2 3). Accordingly, eight Scenario Models are selected. Specifically, eight Scenario Models are generated in the decision tree generation 108 (generated separately from the Scenario Models generated by the scenario modeling unit 101). Note that “Asset” illustrated in FIGS. 15 and 16 is a Physical Asset. In addition, “CPU” illustrated in FIGS. 15 and 16 is a CPU in the real world 67.

The priority order of the Factors may be as follows in a descending order: Data type, Asset Status, and CPU Status. “Common” in the Data type column may mean that the sensor measurement value satisfies the condition based on the threshold of the sensor measurement value, and “Rare” in the Data type column may mean that the sensor measurement value does not satisfy the condition based on the threshold of the sensor measurement value. “Healthy” in the Asset Status column may mean that the Factor value related to the condition satisfies the condition based on the threshold of the Factor value, and “Near Breakdown” in the Asset Status column may mean that the Factor value related to the condition does not satisfy the condition based on the threshold of the Factor value. “Free” in the CPU Status column may mean that the CPU usage rate satisfies the condition based on the threshold of the CPU usage rate, and “Busy” in the CPU Status column may mean that the CPU usage rate does not satisfy the condition based on the threshold of the CPU usage rate.

For each of the two Outcomes (Accuracy, Execution Speed), the model selection unit 103 determines, for each model class, an Outcome value range based on the comparison result (the comparison result between the Factor value and the threshold) corresponding to the model class. The model selection unit 103 generates or selects, for each model class, the Scenario Model having the Outcome values belonging to respective ones of the Outcome value ranges of the model class (for example, selects from the model area 605 or the scenario library 607).

FIG. 16 illustrates a second example of the decision tree generation 108.

There are four Factors (Input, Data type, Asset Status, and CPU Status), and there are three Outcomes (Accuracy, Execution Speed, and Signal-Noise Ratio) under the four Factors. Since n=4, 16 model classes are generated (16=2 4). Accordingly, 16 Scenario Models are selected.

“Input” means the input type. “Calculated Data” in the Input column may mean the Asset Data 809, and “Modelled Data” in the Input column may mean the Scenario Set Data 817. The priority order of the Factors may be as follows in a descending order: Input, Data type, Asset Status, and CPU Status. Note that the above-described Expected Behavior 829 helps the system 203 understand a range of an expected value.

For each of the three Outcomes (Accuracy, Execution Speed, and Signal-Noise Ratio), the model selection unit 103 determines, for each model class, an Outcome value range based on the comparison result (the comparison result between the Factor value and the threshold) corresponding to the model class. The model selection unit 103 generates or selects, for each model class, the Scenario Model having the Outcome values belonging to respective ones of the Outcome value ranges of the model class.

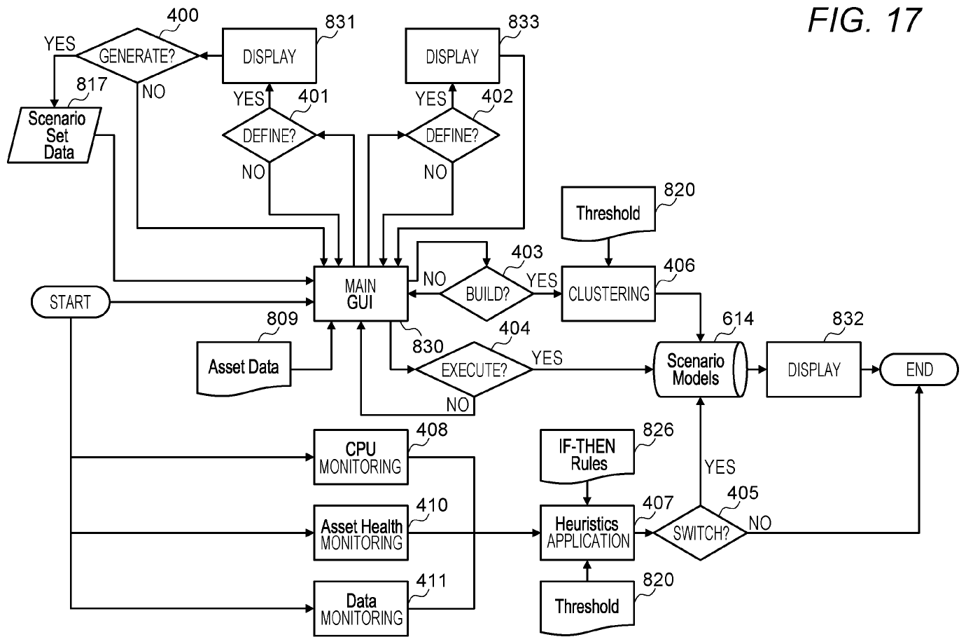

FIG. 17 illustrates an example of details of the model selection 110.

The model selection unit 103 displays the main GUI 104A (see FIG. 4) (reference sign 830). When the button 500 is pressed, the model selection unit 103 reads out the Asset Data 809.

When the button 501 of the main GUI 104A is pressed (reference sign 401: Yes), the model selection unit 103 displays the scenario definition GUI 104B (see FIG. 5) (reference sign 831). When the button 49 is pressed (reference sign 400: Yes), the model selection unit 103 generates Scenario Set Data 817 (reference sign 817).

When the button 509 of the main GUI 104A is pressed (reference sign 402: Yes), the model selection unit 103 displays the Heuristics definition GUI 104C (FIG. 6) (reference sign 833).

When the button 502 of the main GUI 104A is pressed (reference sign 403: Yes), the model selection unit 103 classifies the Scenario Models into a plurality of clusters on the basis of the Threshold 820 (reference sign 406). Scenario Models 614 may include the classified Scenario Models.

When the button 510 of the main GUI 104A is pressed (reference sign 404: Yes), the model selection unit 103 selects a Scenario Model. The selected Scenario Model may be, for example, a Scenario Model corresponding to a manually input query, and may be, for example, a Scenario Model corresponding to the Outcome values having been input to the GUI component group 505 of the main GUI 104A. The Scenario Models 614 may include the Scenario Model. In addition, the Scenario Models 614 may include X number of Scenario Models generated or selected in the decision tree generation 108.

The model selection unit 103 performs CPU monitoring 408, Asset Health monitoring 410, and Data monitoring 411, for example, in the background of the display of the GUI 104. These three functions of the monitoring 408, 410, and 411 correspond to the three Factors (CPU, Asset, and Type) illustrated in FIG. 15. Therefore, when “Input” exemplified in FIG. 16 is included as a Factor, monitoring regarding the Input is also performed in addition to the monitoring 408, 410, and 411 in the background of the display of the GUI 104. Furthermore, data checked in each of these functions of the monitoring is the Asset Data 809. In addition, in a case where it is determined from the results of these functions of the monitoring that the correct Scenario Model suitable for the current situation has not been selected, switching is required (reference sign 405: Yes).

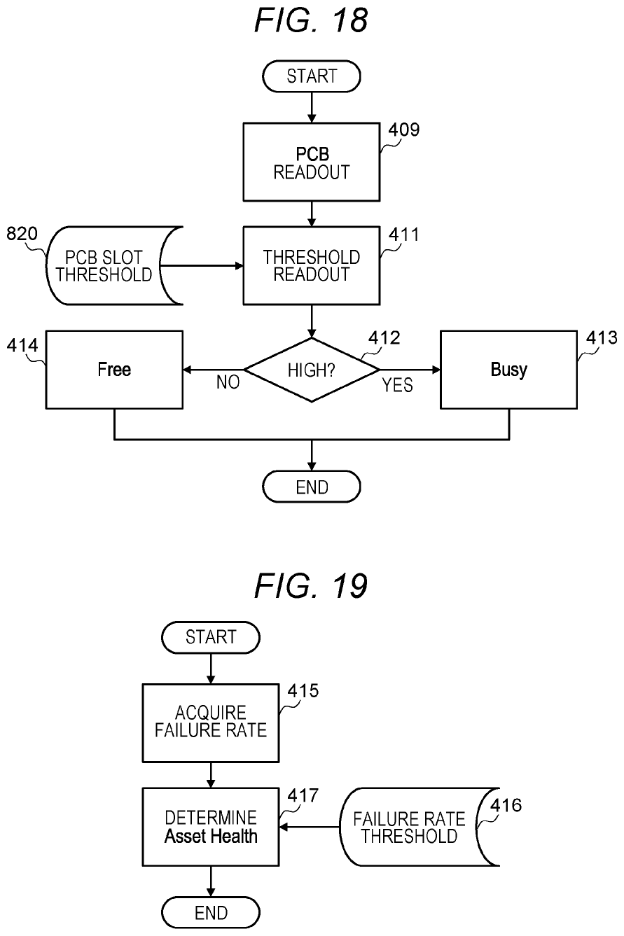

In the CPU monitoring 408, as illustrated in FIG. 18, the model selection unit 103 reads out a process control block (PCB) (reference sign 409) and determines the number of consumed PCB slots (for example, the number of processes). The model selection unit 103 reads out a PCB slot threshold 820 (data representing the threshold of the PCB slot) (reference sign 411). If the number of consumed PCB slots is greater than or equal to the threshold (reference sign 412: Yes), the model selection unit 103 determines that the CPU Status is “Busy” (reference sign 413). If the number of consumed PCB slots is less than the threshold (reference sign 412: No), the model selection unit 103 determines that the CPU Status is “Free” (reference sign 414). Although the CPU Status is monitored as described above, the CPU Status may be monitored on the basis of other values related to the CPU such as the CPU usage rate. The CPU to be monitored is an example of a processor, and may be the CPU of a system that performs digital twin simulation. When the system is the model providing assistance system 203, the CPU to be monitored may be at least part of the processor 213.

In the Asset Health monitoring 410, as illustrated in FIG. 19, the model selection unit 103 acquires a failure rate on the basis of the Asset Data 809 (reference sign 415), and determines the Asset Health on the basis of the failure rate and a failure rate threshold 416 (data representing the failure rate threshold) (reference sign 417).

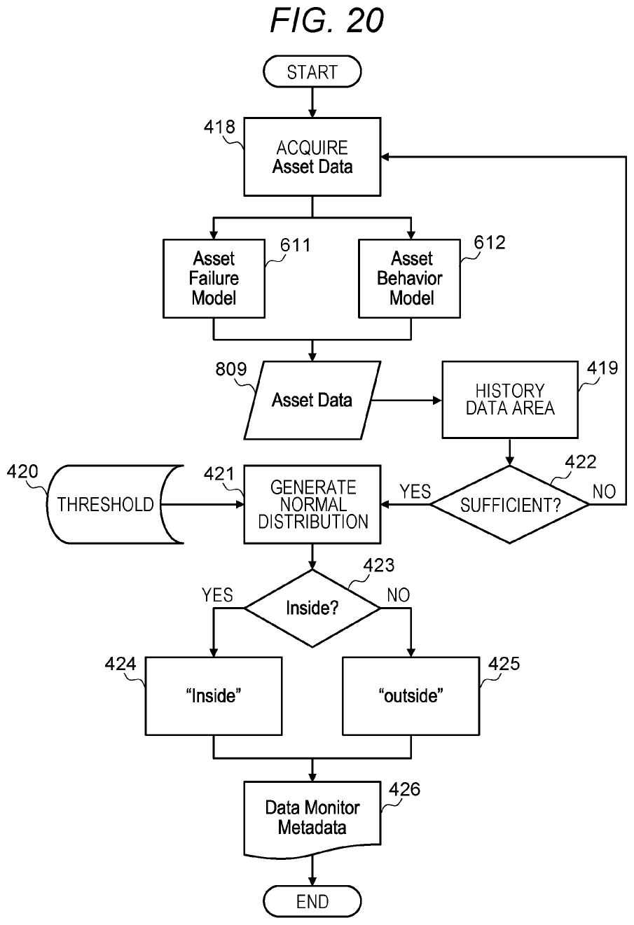

In the data monitoring 411, as illustrated in FIG. 20, the model selection unit 103 acquires Asset Data (reference sign 418). This Asset Data may be data acquired from the real world 67 itself (for example, sensor data) or data obtained on the basis of the data acquired from the real world 67. Furthermore, the Asset Data may be data obtained by inputting the data to the Asset Structure Model 610. The model selection unit 103 obtains the Asset Data 809 by inputting the acquired Asset Data to the Asset Failure Model 611 and the Asset Behavior Model 612, and stores the Asset Data 809 in the history data area 603. The Asset Data 809 may be the data acquired from the real world 67 itself. If there is sufficient data to generate a normal distribution (reference sign 422: Yes), the model selection unit 103 generates a normal distribution with respect to a current data point (time stamp) on the basis of the Asset Data 809, and compares a value (value representing how rare a value is when compared with past data) obtained from the normal distribution with a threshold 420 (data representing a threshold of a value related to the normal distribution) (reference sign 421). The threshold may be a value having been input via the GUI component group 503 of the main GUI 104A. If the obtained value satisfies a condition based on the threshold (reference sign 423: Yes), the model selection unit 103 attaches a label indicating “Inside” to the current data point (reference sign 424). If the obtained value does not satisfy the condition based on the threshold (reference sign 423: No), the model selection unit 103 attaches a label indicating “Outside” to the current data point (reference sign 424). The model selection unit 103 generates Data Monitor Metadata 426 that is data including an attached label and indicates a monitoring result, and stores the Data Monitor Metadata 426 in, for example, the metadata area 823.

Again, with reference to FIG. 17. After the monitoring 408, 410, and 411 described above, the model selection unit 103 receives, from the user, a change of an element (for example, the number of the Factors, the number of the Outcomes, and the range of the Outcome value for at least one Outcome) of the decision tree in the decision tree generation 108 on the basis of at least one of the IF-THEN Rules 826 and the Threshold 820 (reference sign 407). As a result, when switching of models is necessary (reference sign 405: Yes), the model selection unit 103 switches the selected Scenario Model to another Scenario Model. The Scenario Models 614 may include the Scenario Model after the switching.

The model selection unit 103 displays a GUI (for example, a model selection result GUI 104D) showing the result of the processing on the basis of the Scenario Models 614 (reference sign 832).

The model may be selected depending on a function defined by the user (function of Heuristics and/or determination). For example, a decision tree may be generated on the basis of a definition of the user that “when the CPU is in a busy state, a model with low accuracy is prioritized”, and a model with low accuracy may be preferentially selected following the decision tree.

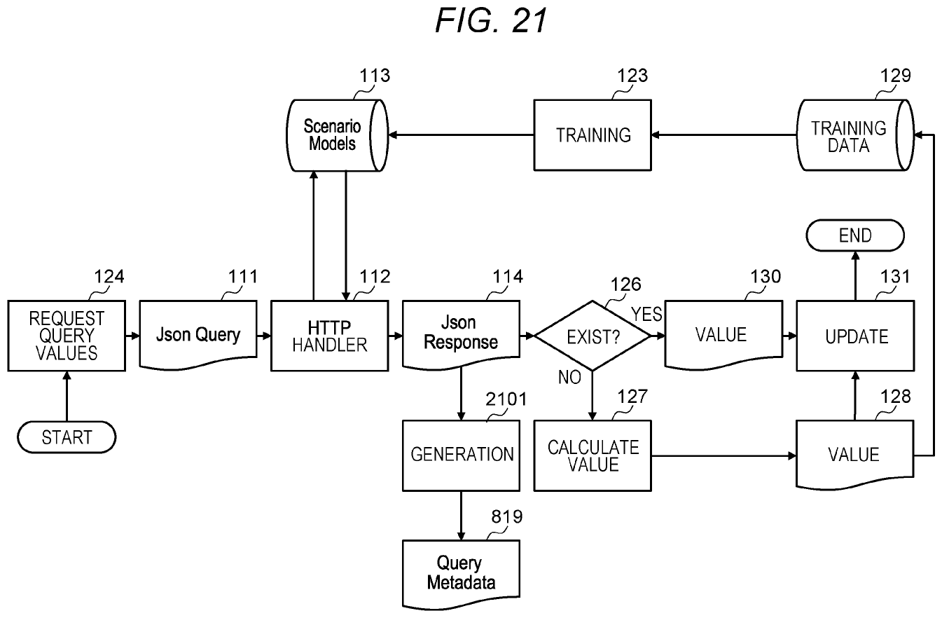

Furthermore, a difference between the model selected in the model selection and the model corresponding to the query in FIG. 21 is in “clustering”. Although the Scenario Model can be queried, a plurality of models are classified into a plurality of clusters to help the user choose a model for the optimal situation (clustered Scenario Models are generated). The relationship between the model selected in the model selection and the model corresponding to the query in FIG. 21 is that a single Scenario Model includes full data and clustered Scenario Models include partial incremental data of the same data. This is to ensure that each clustered Scenario Model behaves to meet a required level of accuracy.

FIG. 21 illustrates an example of details of the query generation 834.

For example, the model selection unit 103 issues, via an application programming interface (API), a Json Query 111 (an example of the query) in order to request query values (reference sign 124). Json is an abbreviation of JavaScript Object Notification (JavaScript is a registered trademark). The requested values may be the values of the first and second explanatory variables, and are acquired from, for example, the Asset Data 809 (or the Expected Behavior 829) and set as values in the Json Query 111. In addition, the objective variable is set as a query key in the Json Query 111. Note that the value set in the Json Query 111 may be manually input.

In response to the Json Query 111, an HTTP handler 112, which may be an example of a function of the model selection unit 103, acquires a value (for example, the Scenario Model or the ID of the Scenario Model) from the Scenario Models 113 and returns a Json Response 114 (an example of the response to the query) having the acquired value. The Scenario Models 113 may include a Scenario Model that is at least some of the Scenario Models 614, may include at least one Scenario Model in the model area 605, or may include at least one Scenario Model in the scenario library 607. Further, the Scenario Models 113 may be cached Scenario Models (Scenario Models stored in the cache area 602).

When the value corresponding to the query values (for example, the values of the first and second explanatory variables) designated by the Json Query 111 can be specified from the Scenario Models 113 with respect to the query key designated by the Json Query, the value is set in the Json Response 114.

The model selection unit 103 generates the Query Metadata 819 on the basis of the Json Response 114 (reference sign 2101).

Furthermore, if a value exists in the Json Response 114 (reference sign 126: Yes), the model selection unit 103 acquires the value 130 and updates the digital twin simulator (reference sign 131). Specifically, if the model includes an out-of-range value (a value that is not found when queried), the model is replaced with a newly trained model, and the replacement is an update of the digital twin simulator.

On the other hand, if no value exists in the Json Response 114 (reference sign 126: No), the model selection unit 103 calculates the value 128 (reference sign 127), and updates the digital twin simulator on the basis of the calculated value 128 (reference sign 131). For example, the model selection unit 103 may calculate the value 128 with respect to the query key on the basis of the query value and the Scenario Set Data 817. The model selection unit 103 generates training data 129 using the calculated value 128 and trains (learns) at least one or some of the Scenario Models 113. The training data 129 may be, for example, data including the query value and the calculated value 128. Furthermore, the Asset Data 809 in the history data area 603 is used to generate the Scenario Data from a query value that is not found. The new Scenario Model is trained using the Scenario Data.

Three variables (for example: A, B, and C) may be used for query for a model, and at least two values may be required to determine one value. For example, the values of A and B may be required for query for the value of C. The variables A and B may be manually input to obtain C. However, the query may be automatically constructed by searching the Scenario Data. In a case where the value of A is given and no new input is performed, it can be considered that the value of B does not change, so that the value of B may be extracted from the Scenario Data. That is, a model may be searched for by manually inputting the values of A and B for the query for the value of C. Alternatively, in a case where the input is not changed from the Asset Data 809 in the history data area 603, the value of A or B may be manually input, and the corresponding value may be searched for using the Scenario Data, so that a query for the remaining variable may be automatically generated.

One embodiment has been described above, but this embodiment is an example to describe the present invention, and it is not intended to limit the scope of the present invention only to this embodiment. The present invention can be carried out in various other forms.

The above description can be summarized, for example, as follows. The following summary may include supplementary description of the above description and include description of variations.

The model providing assistance system 203 includes: an interface apparatus 211 that receives physical asset data (for example, Asset Data) that is data related to a physical asset (for example, a real world 67); a storage apparatus 212 that stores the physical asset data; and a processor 213 connected to the interface apparatus 211 and the storage apparatus 212. The processor 213 determines a plurality of model classes that are each a model class of a scenario model, based on: (i) one or more model factors that are one or more different factors with respect to the scenario model for a digital twin simulator, the one or more model factors being specified from Asset Data (or digital asset data corresponding to the Asset Data); and (ii) a result of comparison, for each model factor of the one or more model factors, between a value for the each model factor and a threshold of the each model factor. For each of the plurality of model classes and for each model outcome of one or more model outcomes that are one or more different outcomes with respect to the scenario model, the processor 213 receives, from the user, an outcome value range that is a range of a value of the each model outcome and is a range of a value based on heuristics. The processor 213 prepares, for each model class of the plurality of model classes, a scenario model having an outcome value belonging to the outcome value range received for the each model class. The processor 213 selects an optimal scenario model from among the scenario models prepared for respective ones of the model classes. In this way, even when a scenario has a large number of dimensions, a high-speed search for the optimal scenario model to be applied to the digital twin simulator is possible.

The one or more model factors may include at least one of the followings: a processor load (for example, CPU Status), a status of asset (for example, Asset Status), scarcity of data point (for example, Data type), and a type of input data (for example, Input). The one or more model outcomes may include at least one of the followings: accuracy, an execution speed, a building requirement time, and a signal-to-noise ratio (Signal-Noise Ratio). These examples of the model factor and the model outcome contribute to a high-speed search for the optimal scenario model to be applied to the digital twin simulator even when the number of dimensions of the scenario is large.

The processor 213 may generate a decision tree in which each of the plurality of model classes is a leaf node. In the decision tree, a root node or an intermediate node is a comparison between a value obtained for the model factor corresponding to the node and a threshold corresponding to the model factor, and the next node may be determined depending on a result of the comparison. The processor 213 may monitor a value for each of the plurality of model factors. The optimal scenario model may be a scenario model determined by following the decision tree on the basis of the monitored value and the threshold for each model factor. This contributes to a high-speed search for the optimal scenario model to be applied to the digital twin simulator even when the number of dimensions of the scenario is large.

The optimal scenario model may be a scenario model having the largest query hit rate. This contributes to a high-speed search for the optimal scenario model to be applied to the digital twin simulator even when the number of dimensions of the scenario is large.

Each scenario model may be a response surface methodology (RSM) model to predict the response.

In addition, each of the scenario models may be a model generated on the basis of a scenario set including a plurality of scenarios that are each a combination of an objective variable value and one or more values of explanatory variables. The processor 213 may generate digital asset data corresponding to the physical asset data and is input to the digital twin simulator, by inputting the physical asset data to an asset model for each viewpoint, may build the scenario model by specifying a value range for each variable on the basis of the digital asset data. The objective variable value may be an output value as a calculation result of the digital twin simulation, and the one or more explanatory variables may be one or more features specified from data that is input to the digital twin simulation.

The plurality of model classes may be a plurality of model clusters based on one or more designated criteria, and each model cluster may be a set of one or more scenario models.

What is claimed is:

1. A model providing assistance system comprising:
an interface apparatus that receives physical asset data that is data related to a physical asset;
a storage apparatus that stores the physical asset data; and
a processor connected to the interface apparatus and the storage apparatus,
wherein
the processor determines a plurality of model classes that are each a model class of a scenario model, based on:
one or more model factors that are one or more different factors with respect to the scenario model for a digital twin simulator, the one or more model factors being specified from the physical asset data or digital asset data corresponding to the physical asset data, and
a result of comparison, for each model factor of the one or more model factors, between a value for the each model factor and a threshold of the each model factor,
the processor receives from a user, for each of the plurality of model classes and for each model outcome of one or more model outcomes that are one or more different outcomes with respect to the scenario model, an outcome value range that is a range of a value of the each model outcome and is a range of a value based on heuristics,
the processor prepares, for each model class of the plurality of model classes, a scenario model having an outcome value belonging to the outcome value range received for the each model class, and
the processor selects an optimal scenario model from among the scenario models prepared for respective ones of the model classes.

2. The model providing assistance system according to claim 1, wherein
the one or more model factors include at least one of a processor load, a status of asset, scarcity of data point, and a type of input data, and
the one or more model outcomes include at least one of accuracy, an execution speed, a building requirement time, and a signal-to-noise ratio.

3. The model providing assistance system according to claim 1, wherein
the processor generates a decision tree in which each of the plurality of model classes is a leaf node,
a root node or an intermediate node is a comparison between a value obtained for the model factor corresponding to the node and a threshold corresponding to the model factor, and a next node is determined depending on a result of the comparison,
the processor monitors a value for each of the plurality of model factors, and
the optimal scenario model is a scenario model determined by following the decision tree, based on the monitored value and the threshold for each model factor.

4. The model providing assistance system according to claim 1, wherein
the optimal scenario model is a scenario model having a largest query hit rate.

5. The model providing assistance system according to claim 1, wherein
each scenario model is a response surface methodology (RSM) model.

6. The model providing assistance system according to claim 1, wherein
each scenario model is a model generated based on a scenario set including a plurality of scenarios that are each a combination of an objective variable value and one or more values of explanatory variables,
the processor generates digital asset data corresponding to the physical asset data and is input to the digital twin simulator, by inputting the physical asset data to an asset model for each viewpoint, and
the processor builds the scenario model by specifying a value range for each variable, based on the digital asset data.

7. The model providing assistance system according to claim 6, wherein
the objective variable value is an output value as a calculation result of the digital twin simulation, and
the one or more explanatory variables are one or more features specified from data that is input to the digital twin simulation.

8. The model providing assistance system according to claim 1, wherein
the plurality of model classes are a plurality of model clusters based on one or more designated criteria, and
each of the plurality of model clusters may be a set of one or more scenario models.

9. A model providing assistance method comprising:
determining, by a processor, a plurality of model classes that are each a model class of a scenario model, based on:
one or more model factors that are one or more different factors with respect to the scenario model for a digital twin simulator, the one or more model factors being specified from the physical asset data or digital asset data corresponding to the physical asset data, and
a result of comparison, for each model factor of the one or more model factors, between a value for the each model factor and a threshold of the each model factor;
receiving, by the processor, from a user, for each of the plurality of model classes and for each model outcome of one or more model outcomes that are one or more different outcomes with respect to the scenario model, an outcome value range that is a range of a value of the each model outcome and is a range of a value based on heuristics;
preparing, by the processor, for each model class of the plurality of model classes, a scenario model having an outcome value belonging to the outcome value range received for the each model class; and
selecting, by the processor, an optimal scenario model from among the scenario models prepared for respective ones of the model classes.
